(19) United States
(12) Patent Application Publication
(10) Pub. No.: US 2010/0109060 A1
(43) Pub. Date: May 6, 2010

(54) IMAGE SENSOR WITH BACKSIDE PHOTODIODE IMPLANT

(75) Inventors: Duli Mao, Sunnyvale, CA (US); Vincent Venezia, Sunnyvale, CA (US); Hsin-Chih Tai, Cupertino, CA (US); Yin Qian, Milpitas, CA (US); Howard E. Rhodes, San Martin, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES INC., Santa Clara, CA (US)

(21) Appl. No.: 12/266,314

(22) Filed: Nov. 6, 2008

(51) Int. Cl. H01L 31/18; H01L 27/146

(52) U.S. Cl. 257/292; 438/59; 257/E27.133; 257/E31.001

(57) ABSTRACT

An array of pixels is formed using a substrate. Each pixel can be formed on the substrate, which has a backside and a frontside that includes metalization layers. A photodiode is formed in the substrate and frontside P-wells are formed using frontside processing that are adjacent to the photosensitive region. A first N-type region is formed in the substrate below the photodiode. A second N-type region is formed in a region of the substrate below the first N-type region and is formed using backside processing.

This disclosure relates generally to imaging circuits, and more particularly, but not exclusively, relates to image sensors.

### BACKGROUND INFORMATION

Integrated circuits have been developed to reduce the size of components used to implement circuitry. For example, integrated circuits have been using ever-smaller design features, which reduces the area used to implement the circuitry, such that many design features are now well under the wavelengths of visible light. With the ever-decreasing sizes of image sensors and the individual pixels that are part of a sensing array, it is important to more efficiently capture incident light that illuminates the sensing array. Thus, more efficiently capturing incident light helps to maintain or improve the quality of electronic images captured by the sensing arrays of ever-decreasing sizes.

### BRIEF DESCRIPTION OF THE DRAWINGS

Non-limiting and non-exhaustive embodiments of the disclosure are described with reference to the following figures, wherein like reference numerals refer to like parts throughout the various views unless otherwise specified.

FIG. 1 is a cross-section of a backside illuminated conventional image sensor pixel.

FIG. 2 is a cross-section illustrating a backside illuminated image sensor pixel having a backside photodiode implant.

FIG. 3 is a cross-section illustrating a sample sensor array of backside illuminated (BSI) pixel of the CMOS image sensor.

### DETAILED DESCRIPTION

Embodiments of an image sensor are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. The term “or” as used herein is normally meant to encompass a meaning of an inclusive function, such as “and/or.”

In general, integrated circuits comprise circuitry that is employed for a variety of applications. The applications use a wide variety of devices such as logic devices, imagers (including CMOS and CCD imagers), and memory (such as DRAM and NOR- and NAND-based flash memory devices). These devices normally employ transistors for a variety of functions, including switching and amplification of signals.

Transistors are typically formed in integrated circuits by photolithographic processes that are performed on a silicon substrate. The processes include steps such as applying a photolithographic resist layer to the substrate, exposing the resist layer to form a pattern using light (including deep ultra-violet wavelengths), removing the exposed portions (or non-exposed portions depending on the photo-positive or photo-negative resists that are used) of the resist by developing, and modifying the exposed structures, for example, by etching and depositing and/or implanting additional materials to form various structure for electronic components (including transistors).

The term “substrate” includes substrates formed using semiconductors based upon silicon, silicon-germanium, germanium, gallium arsenide, and the like. The term substrate may also refer to previous process steps that have been performed upon the substrate to form regions and/or junctions in the substrate. The term substrate can also include various technologies, such as doped and undoped semiconductors, epitaxial layers of silicon, and other semiconductor structures formed upon the substrate.

Chemical-mechanical planarization (CMP) can be performed to render the surface of the modified substrate suitable for forming additional structures. The additional structures can be added to the substrate by performing additional processing steps, such as those listed above.

As the size of the image sensors in individual pixels that are part of a sensing array become increasingly smaller, various designs attempt to more efficiently capture the incident light that illuminates the sensing array. For example, the area of the light sensing element (such as a photodiode) of a pixel is typically maximized by arranging a microlens over (or underneath) each pixel so that the incident light is better focused onto the light sensing element. The focusing of the light by the microlens attempts to capture light that would otherwise normally be incident upon the pixel outside the area occupied by the light sensitive element (and thus lost and/or “leaked” through to other unintended pixels).

Another approach that can be used is to collect light from the “backside” of (e.g., underneath) the CMOS image sensor. Using the backside of the image sensor allows photons to be collected in an area that is relatively unobstructed by the many dielectric and metal layers that are normally included in a typical image sensor. A backside illuminated (BSI) image sensor can be made by thinning the silicon substrate of the image sensor, which reduces the amount of silicon through which incident light traverses before the sensing region of the image sensor is encountered.

However, when thinning the substrate of the image sensor, a tradeoff between the sensitivity of the pixel and crosstalk (with adjacent pixels) is encountered. For example, when less thinning is used (which results in a thicker remaining silicon substrate), a larger (volumetric) region of a photodiode for conversion of light to electron-hole pairs can be provided. When the electron-hole pairs are formed relatively far away (in the larger provided region) from the photodiode depletion region, the formed electron-hole pairs are more likely to be captured by adjacent photodiodes. The capturing of the formed electron-hole pairs by adjacent photodiodes is normally an undesired effect called electrical cross-talk (which causes adjacent pixels to appear to be brighter than the “true” value and can degrade color fidelity of the output). Accordingly, the probability of electrical cross-talk increases with the thickness of the silicon substrate, while sensitivity decreases as the thinner silicon substrates are used.

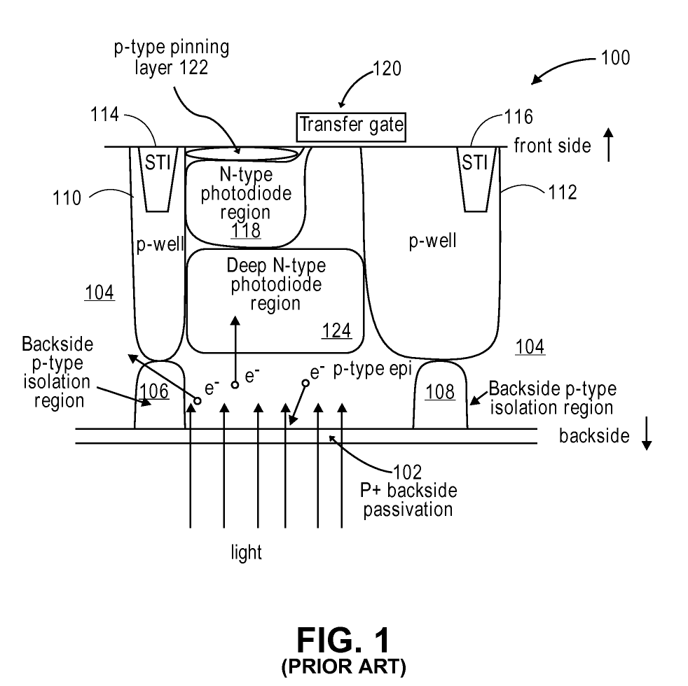

FIG. 1 is a cross-section of a backside illuminated conventional image sensor pixel. The image sensor 100 includes a P-type epitaxial region 104. P-wells 110 and 112 are formed in the P-type epitaxial region 104. Shallow-trench isolation region 114 is formed within P-well 110 and shallow-trench isolation region 116 is formed within P-well 112. P-wells 106 and 108 are “deep” P-type isolation regions between pixels and can be formed by performing a P-type isolation implantation from the backside.

N-type implant and/or diffusion region 124 is formed in epitaxial region 104 in a region that is between P-well 110 and P-well 112. The N-type implant and/or diffusion region 124 typically extends vertically from the N-type photodiode region 118 on downwards to within a fraction of a micron of the backside surface. N-type photodiode region 118 can be formed by implanting N-type dopants in epitaxial region 104 in a region that is above N-type implant and/or diffusion region 124. A P-type pinning layer 122 is implanted in a region that is above N-type photodiode region 118. Transfer gate 120 is formed above epitaxial region 104 to control transfer of electrons from N-type photodiode region 118 for detection of photo-generated electrons. Passivation layer 102 is a shallow region that is typically less than 0.2 μm thick disposed near the P-type backside surface.

In operation, the majority of photon absorption occurs near the back surface for BSI devices. However, non-uniformity of final silicon thickness in BSI devices results in a phenomenon called photo-response non-uniformity (PRNU). If the photodiode implant is done only during front side silicon processing, the non-uniform silicon thickness often results in variations in the doping profile when viewed from the backside. The variations in the doping profile can cause pixel to pixel variations in terms of charge separation and collection, which leads to a higher PRNU. When using non-SOI (silicon on insulator) wafers, the silicon thickness variation typically ranges from several hundred angstroms to several thousand angstroms. The resulting silicon thickness variation is high enough to cause very high PRNUs and visible artifacts in images resulting from the image sensor having the PRNU.

PRNU can be reduced by improving the uniformity of the silicon thinning process. Improving the uniformity of the silicon thinning process can be accomplished by choosing the proper method and chemicals and by using etch-stop layers that are defined during front-side silicon processing. Silicon thickness uniformity can be obtained by using SOI starting wafers and using the oxide layer serving as the etch-stop-layer during backside silicon thinning. However, SOI wafers are typically relatively expensive as compared to non-SOI wafers.

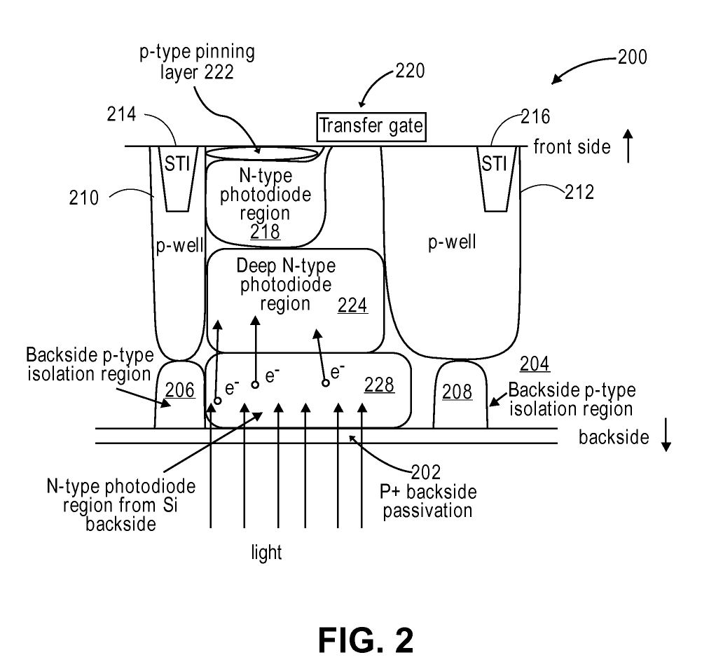

FIG. 2 is a cross-section illustrating a backside illuminated image sensor pixel having a backside photodiode implant. The image sensor 200 includes a P-type epitaxial region 204. P-wells 210 and 212 are formed in the P-type epitaxial region 204. Shallow-trench isolation region 214 is formed within P-well 210 and shallow-trench isolation (STI) region 216 is formed within P-well 212. (Although an STI structure is illustrated, other isolation structures using local oxidation of silicon, for example, can be used.) P-wells 206 and 208 are “deep” P-type isolation regions between pixels and can be formed by using a P-type isolation implantation or diffusion from the backside.

N-type implant and/or diffusion region 224 is formed in epitaxial region 204 in a region that is between P-well 210 and P-well 212. The N-type implant and/or diffusion region 224 typically extends vertically from the N-type photodiode region 218 on downwards to within a fraction of a micron of the backside surface. N-type photodiode region 218 can be formed by implanting N-type dopants in epitaxial region 204 in a region that is between P-wells 210 and 212 and above N-type implant and/or diffusion region 224. A P-type pinning layer 222 is implanted in a region that is above N-type photodiode region 218. A transfer gate 220 is formed above epitaxial region 204 to control transfer of electrons from N-type photodiode region 218 for detection of photo-generated electrons.

Backside N-type photodiode implant 228 is formed near the backside surface of sensor 200. Backside N-type photodiode implant 228 extends an N-type region (e.g., including N-type implant and/or diffusion region 224 and N-type photodiode region 218) from under P-type pinning region 222 to near the backside surface of sensor 200, which includes passivation layer 202. Passivation layer 202 is a shallow region that is typically less than 0.2 μm thick disposed near the P-type backside surface.

The doping provided by backside N-type photodiode implant 228 enhances a vertical electric field near the back surface where most of the light absorption and electron-hole pair generation occur. As a result, the photo-generated electron-hole pairs are separated more effectively, which yields higher quantum efficiency and sensitivity. Backside N-type photodiode implant 228 ensures that the junction depth is the same across the entire pixel array (as measured from the backside), even though the silicon thickness variation can be large due to non-uniformity of the silicon thinning process. The improved junction depth uniformity in turn improves the uniformity of charge separation and collection, which leads to improved PRNU.

Performing N-type implantation from the backside requires a much lower energy implant than what is needed when implanting from the front side. Accordingly, thinner photoresists and tighter design rules can be used for patterning and larger fill factor of the n-type photodiode implant can be achieved. The thinner photoresists and tighter design rules results in higher sensitivity image sensors.

In an embodiment, the backside N-type implants 228 can be implanted while using a photo mask to limit the implants to a center region of the photodiodes in a pixel array. Alternatively, the backside N-type implants 228 can be performed across the entire face of the pixel array (such that, for example, a photo-mask is not required for masking isolation regions between pixels when performing the backside N-type implant. Where the backside N-type implants 228 are performed across the entire face of the pixel array, a P-type isolation implant is used to separate the N-type regions to reduce electrical cross-talk.

Because both the N-type photodiode implant and the P-type isolation implant are performed using backside processing, the size and location of the photodiode region are defined primarily by backside silicon processing, so that relatively better alignment can be achieved between the photodiode region and color filter and micro-lens. Better alignment can be achieved because all backside patterning is done with reference to the backside alignment marks, which are not always perfectly aligned to the front side alignment marks.

An example dose of the backside N-type implant can be between 10¹¹ and 10¹² ions/cm² and can have an implant depth from less than 0.1 μm to about 1 μm. The example dose and energy is typically beneficial for effective dopant activation by post-implant laser annealing and is typically beneficial for better charge collection by photodiodes regions.

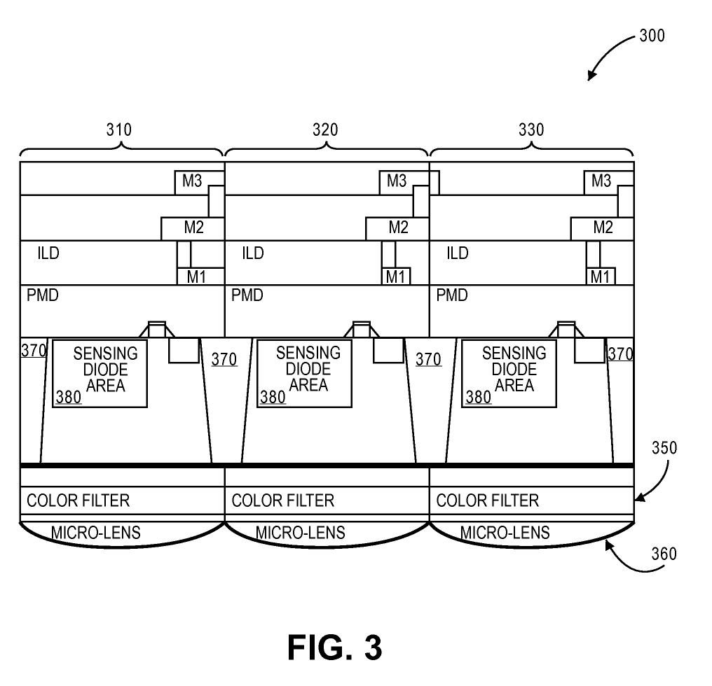

To illustrate the arrangement of the image sensor pixel in a sensor array, FIG. 3 shows a cross-section of a sample sensor array of backside illuminated (BSI) pixel of the CMOS image sensor. Array 300 includes pixels 310, 320, and 330. Structure 300 typically contains at least thousands of pixels and often contains more than a million pixels. An isolation region 370 separates pixels. Sensing diode area 380 can be, for example, the N-type photodiode regions, as described above with respect to FIG. 2. Three pixels are shown for the purpose of clarity.

The pixels of array 300 are typically arranged in a two-dimensional array such that an electronic image can be formed in response to incident light being captured by each pixel. Each pixel can have a filter 350 (including color filters and infra-red filters) such that the electronic image can be used, for example, to capture color images or increase the sensitivity of the pixel to certain wavelengths of light. Each pixel can also have a micro-lens 360 associated with each pixel such that the incident light is more directly guided into the pixel.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

1. An image sensor, comprising:
an array of pixels formed using a substrate, wherein a plurality of the pixels each have:
a substrate having a backside and a frontside that includes metalization layers;
a photodiode region formed in the substrate;
frontside wells of a first polarity formed using frontside processing that are adjacent to the photodiode, the wells of a first polarity forming electron barrier regions between pixels, and the wells of a first polarity having an associated depth with respect to the frontside;
a first region of a second polarity formed in the substrate below the photodiode region, and
a second region of the second polarity being formed using backside processing at least in part in a region of the substrate that is between the frontside wells of the first polarity.

2. The apparatus of claim 1, wherein the substrate includes epitaxial silicon.

3. The apparatus of claim 1, further comprising an isolation region of the first polarity being formed using backside processing in a region that is beneath at least one of the frontside wells of the first polarity.

4. The apparatus of claim 1, wherein the second region of the second polarity extends vertically from a passivation layer on a backside surface of the substrate to the first region of the second polarity.

5. The apparatus of claim 1, wherein portions of the first and second regions of the second polarity are between a pinning implant structure on the frontside of the substrate and a passivation structure on the backside of the substrate.

6. The apparatus of claim 1, wherein the pinning implant structure and the passivation structure are of the first polarity.

7. The apparatus of claim 1, wherein the second region of the second polarity is diffused using backside processing.

8. The apparatus of claim 1, wherein the second region of the second polarity is implanted using backside processing.

9. The apparatus of claim 1, wherein the second region of the second polarity comprises dopants of the first polarity and dopants of the second polarity.

10. The apparatus of claim 9, wherein an P-type dopant concentration of the second region of the second polarity is less than an N-type dopant concentration of the second region of the second polarity.

11. The apparatus of claim 1, further comprising backside wells of the first polarity formed using backside processing.

12. The apparatus of claim 11, wherein the backside wells of the first polarity are formed in a region of the substrate that is at least partly beneath a corresponding frontside well of the first polarity.

13. The apparatus of claim 11, wherein the second region of the second polarity is formed using a backside N-type implanted dopant having a dose of between about 10¹¹ and 10¹² ions/cm²

14. The apparatus of claim 1, wherein the second region of the second polarity is formed using a backside N-type implanted dopant at a depth from about 0.1 μm to about 1 μm.

15. A method, comprising:
forming an array of photosensitive regions within a substrate having a backside and a frontside;
using frontside processing to form frontside isolation regions, each isolation region being formed in a region that is between a pair of the photosensitive regions in the array of photosensitive regions, wherein the each of the pair of photosensitive regions are isolated from the other by the other of the pair of photosensitive regions by one of the frontside isolation regions;
forming a first N-type region formed in the substrate below the photodiode using frontside processing;
forming a second N-type region formed in the substrate below the photodiode using frontside processing;
forming a third N-type region formed in the substrate below the photodiode using backside processing; and
forming a transfer gate for capturing electrons generated photo-electrically in the N-type region.

16. The method of claim 15, further comprising using backside processing to form backside isolation regions.

17. The method of claim 16, wherein the backside isolation regions are formed underneath corresponding frontside isolation regions.

18. A method, comprising:
forming a photosensitive region within a substrate having a backside and a frontside;
using frontside processing to form frontside P-wells that are adjacent to the photosensitive region, the P-wells forming electron barrier regions between pixels;
using backside processing to form backside P-wells that are under the frontside P-wells;
forming a first N-type region in the substrate below the photodiode using frontside processing, the first N-type region being formed between the frontside P-wells; and
forming a second N-type region in the substrate below the photodiode using backside processing.

19. The method of claim 18, wherein the backside P-wells are formed by using an implant process that does not use a photo mask for masking isolation regions between pixels.

20. The method of claim 19, wherein the backside P-wells are formed by using an implant process that uses a photo mask for masking isolation regions between pixels.

21. An image sensor, comprising:
a pixel formed using a substrate, comprising:
a substrate having a backside and a frontside that includes metalization layers;
a photodiode region formed in the substrate;
frontside P-wells formed using frontside processing that are adjacent to the photosensitive region, the P-wells forming electron barrier regions between the pixel and adjacent pixels, and the P-wells having an associated depth with respect to the frontside; and
a backside N-type region formed in the substrate below the photodiode using backside processing, the backside N-type region being formed only in a region of the substrate that is deeper than the depth of the frontside P-wells.

22. The apparatus of claim 21, further comprising backside P-wells formed in a region of the substrate that is at least partly beneath a corresponding frontside P-well.

23. The apparatus of claim 22, wherein the backside N-type region comprises a P-type dopant implanted during formation of the backside P-wells.

24. The apparatus of claim 21, further comprising lens provided on a backside surface of the substrate, wherein the lens is arranged to direct light towards the photodiode region.
